(19) United States
(12) Patent Application Publication
(10) Pub. No.: US 2014/0007934 A1
(43) Pub. Date: Jan. 9, 2014

(54) THIN FILM SOLAR CELL AND METHOD OF FABRICATING THE SAME

(71) Applicant: ELECTRONICS AND TELECOMMUNICATIONS RESEARCH INSTITUTE, Daejeon (KR)

(72) Inventors: Sun Jin YUN, Daejeon (KR); JungWook Lim, Daejeon (KR)

(73) Assignee: Electronics and Telecommunications Research Institute, Daejeon (KR)

(21) Appl. No.: 13/867,565

(22) Filed: Apr. 22, 2013

(30) Foreign Application Priority Data
Jul. 6, 2012 (KR) 10-2012-0074083
Nov. 7, 2012 (KR) 10-2012-0125499

(51) Int. Cl. H01L 31/0216

(52) U.S. Cl. CPC H01L 31/02167
USPC 136/256; 438/72

(57) ABSTRACT

A thin film solar cell according to the inventive concept includes a back side electrode on a substrate, a light absorption layer on the back side electrode, a buffer layer on the light absorption layer, a front side transparent electrode on the buffer layer, a grid electrode partially formed on the front side transparent electrode and exposing a top surface of a portion of the front side transparent electrode, and an anti-reflection layer covering the exposed top surface of the front side transparent electrode. The buffer layer includes titanium oxide (TiOₓ).

### CROSS-REFERENCE TO RELATED APPLICATIONS

This U.S. non-provisional patent application claims priority under 35 U.S.C. §119 to Korean Patent Application Nos. 10-2012-0074083 and 10-2012-0125499, filed on Jul. 6, 2012 and Nov. 7, 2012, the entirety of which is incorporated by reference herein.

### BACKGROUND

The inventive concept relates to thin film solar cells and methods of fabricating the same and, more particularly, to compound semiconductor thin film solar cells including a buffer layer and methods of fabricating the same.

A solar cell is a photovoltaic energy conversion system converting the sunlight into electric energy. The sunlight is used as an energy source for making the electric energy in the solar cell. The light is a clean energy source which does not generate toxic substances. Thus, the sunlight is spotlighted as a future environment-friendly energy source capable of substituting for fossil fuel. Thus, various researches have been conducted for the solar cell.

Thin film solar cells may be categorized into an amorphous or crystalline silicon thin film solar cell, a CIGS-based thin film solar cell, a CdTe thin film solar cell. The CIGS-based thin film solar cell belongs to a compound semiconductor solar cell. A CIGS light absorption layer may be formed by adding gallium (Ga) to a CIS compound semiconductor for increasing an energy band gap thereof. Thus, the amount of gallium (Ga) may be controlled to change the energy band gap of the CIGS light absorption layer. The light absorption layer of the CIGS-based thin film solar cell may be formed of a II-III-VI group compound semiconductor such as CuInSe₂ (CIS) and may have a direct transition type energy band gap. Additionally, the light absorption layer of the CIGS-based thin film solar cell may have a large light absorption coefficient, such that a high efficiency solar cell may be fabricated by the thin light absorption layer having a thickness of about 1 μm to about 2 μm.

### SUMMARY

Embodiments of the inventive concept may provide thin film solar cells capable of improving efficiency.

Embodiments of the inventive concept may also provide methods of fabricating a thin film solar cell capable of improving efficiency.

In one aspect, a thin film solar cell may include: a back side electrode formed on a substrate; a light absorption layer formed on the back side electrode; a buffer layer formed on the light absorption layer; a front side transparent electrode formed on the buffer layer; a grid electrode partially formed on the front side transparent electrode, the grid electrode exposing a top surface of a portion of the front side transparent electrode; and an anti-reflection layer covering the exposed top surface of the front side transparent electrode. The buffer layer includes titanium oxide (TiOₓ).

In an embodiment, an atomic ratio “x” of oxygen in the titanium oxide (TiOₓ) may be equal to or greater than 0.75 and smaller than 2.0.

In an embodiment, the buffer layer may have an energy band gap of about 1.15 eV to about 3.3 eV.

In an embodiment, the energy band gap of the buffer layer may gradually increase from an interface between the buffer layer and the light absorption layer to an interface between the buffer layer and the front side transparent electrode.

In an embodiment, the buffer layer may include N-type dopants.

In an embodiment, the buffer layer may have a dopant concentration gradually increasing from an interface between the buffer layer and the light absorption layer to an interface between the buffer layer and the front side transparent electrode.

In an embodiment, the buffer layer may have a dopant concentration gradually decreasing from an interface between the buffer layer and the light absorption layer to an interface between the buffer layer and the front side transparent electrode.

In an embodiment, the light absorption layer may be a CIGS-based light absorption layer or a CZTS-based light absorption layer.

In another aspect, a method of fabricating a thin film solar cell may include: forming a back side electrode on a substrate; forming a light absorption layer on the back side electrode; forming a buffer layer on the light absorption layer; forming a front side transparent electrode on the buffer layer; forming a grid electrode on a partial portion of the front side transparent electrode; forming an anti-reflection layer on the top surface of the front side transparent electrode exposed the grid electrode. The buffer layer includes titanium oxide (TiOₓ).

In an embodiment, the buffer layer may be formed using an atomic layer deposition (ALD) method or a reactive sputtering method.

In an embodiment, the ALD method may include: providing titanium (Ti) precursors in order that the titanium (Ti) precursors are adsorbed onto the light absorption layer; providing a first purge gas including an argon (Ar) gas to remove non-adsorbed titanium (Ti) precursors; providing oxygen precursors to react the titanium (Ti) precursors adsorbed on the light absorption layer with the oxygen precursors, thereby forming titanium dioxide (TiO₂); providing a second purge gas including an argon gas to remove unreacted oxygen precursors and a byproduct generated by the reaction of the adsorbed titanium (Ti) precursors and the oxygen precursors; and reducing the titanium dioxide (TiO₂).

In an embodiment, the reactive sputtering method may use a titanium metal as a sputtering target; and the partial pressure of oxygen (O₂) gas may gradually increase during the reactive sputtering method.

In an embodiment, an energy band gap of the buffer layer may be greater than an energy band gap of the light absorption layer and may be smaller than an energy band gap of the front side transparent electrode; and the energy band gap of the buffer layer may gradually increase from the energy band gap of the light absorption layer to the energy band gap of the front side transparent electrode.

In an embodiment, the method may further include: doping the buffer layer with N-type dopants. A dopant concentration of the buffer layer may be gradually varied in the buffer layer.

In an embodiment, the light absorption layer may be a CIGS-based light absorption layer or a CZTS-based light absorption layer.

### BRIEF DESCRIPTION OF THE DRAWINGS

The inventive concept will become more apparent in view of the attached drawings and accompanying detailed description.

FIG. 1 is a cross-sectional view illustrating a thin film solar cell according to exemplary embodiments of the inventive concept;

FIG. 2 is a flowchart illustrating a method of fabricating a thin film solar cell according to exemplary embodiments of the inventive concept; and

FIGS. 3 to 8 are cross-sectional views illustrating a method of fabricating a thin film solar cell according to exemplary embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

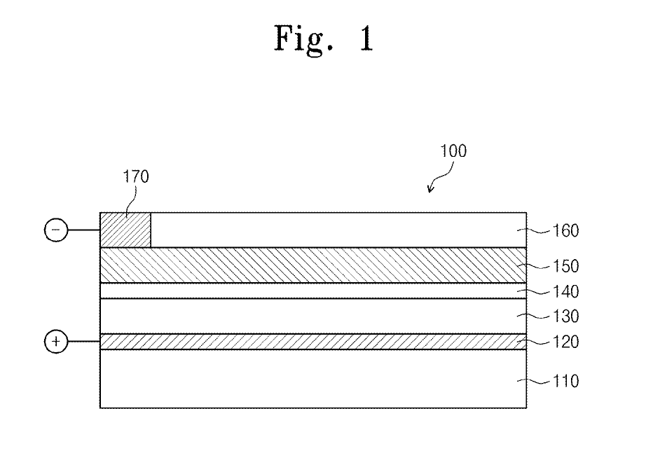

FIG. 1 is a cross-sectional view illustrating a thin film solar cell according to exemplary embodiments of the inventive concept.

Referring to FIG. 1, a thin film solar cell 100 includes a back side electrode 120, a light absorption layer 130, a buffer layer 140, and a front side transparent electrode 150 which are sequentially stacked on a substrate 110. A grid electrode 160 may be formed partially on the front side transparent electrode 150, and an anti-reflection layer 170 may be formed on top surface of a portion of the front side transparent electrode 150 on which the grid electrode 160 is not formed. The thin film solar cell 100 may be a compound semiconductor solar cell adopting light absorbing layer consisting of compound semiconductors.

The substrate 110 may be a soda lime glass substrate. The soda lime glass substrate includes sodium (Na). The sodium (Na) included in the soda lime glass substrate may be diffused into the light absorption layer 130 of the thin film solar cell 100 to contribute to the improvement of a crystal system of the light absorption layer 130. Thus, a photoelectric conversion efficiency of the thin film solar cell 100 may increase. Alternatively, the substrate 100 may be a ceramic substrate such as alumina (Al₂O₃) or quartz, a metal substrate, or a flexible polymer film. The metal substrate may include stainless steel, a copper (Cu) tape, chromium steel, an alloy (kovar) of nickel (Ni) and iron (Fe), titanium, ferritic steel, and/or molybdenum (Mo). The flexible polymer film may include kapton, polyester, or a polyimide film (e.g., Upilex or ETH-PI).

The back side electrode 120 may be formed of a metal or metal alloy. Additionally, a difference between coefficients of thermal expansion of the back side electrode 120 and the substrate 110 may be small for preventing a delamination phenomenon between the back side electrode 120 and the substrate 110. For example, the back side electrode 110 may be formed of molybdenum (Mo). The molybdenum (Mo) may have high conductivity, an excellent ohmic contact property, and thermal stability under a selenium (Se) atmosphere.

The light absorption layer 130 may be formed of II-III-VI₂ group compound semiconductor.

In some embodiments of the inventive concept, the light absorption layer 130 may be a CIGS-based light absorption layer which is formed of, for example, CuInSe₂, Cu(In, Ga)Se₂, Cu(Al, In)Se₂, Cu(Al, Ga)Se₂, Cu(In,Ga)(S,Se)₂, or (Au,Ag,Cu)(In,Ga,Al)(S,Se)₂. The CIGS-based light absorption layer may include a compound semiconductor having one of II group elements including copper (Cu), one of III group elements including indium (In), and one of IV group elements including selenium (Se). In other embodiments, the light absorption layer 130 may be a CZTS-based light absorption layer formed of Cu₂ZnSn(S, Se)₄. The light absorption layer 130 may include a chalcopyrite-based compound semiconductor. The light absorption layer 130 may have an energy band gap of about 1.15 eV to about 1.2 eV.

The buffer layer 140 may have an energy band gap between the energy band gap of the light absorption layer 130 and an energy band gap of the front side transparent electrode 150. For example, the buffer layer 140 may have an energy band gap of about 1.15 eV to about 3.3 eV.

The buffer layer 140 may be formed of titanium oxide (TiOₓ). An energy band gap of the titanium oxide (TiOₓ) may increases as an atomic ratio “x” of oxygen in the titanium oxide (TiOₓ) increases. The atomic ratio “x” of oxygen in the titanium oxide (TiOₓ) is smaller than 2, unlike a general titanium oxide (TiO₂). In some embodiments, the atomic ratio “x” of oxygen in the titanium oxide (TiOₓ) may be equal to or greater than 0.75 and smaller than 2.0 (i.e., 0.75≦x<2.0). Thus, the buffer layer 140 including the titanium oxide (TiOₓ) may have the energy band gap between the energy band gap of the light absorption layer 130 and the energy band gap of the front side transparent electrode 150.

The energy band gap of the buffer layer 140 including the titanium oxide (TiOₓ) may be continuously varied in the buffer layer 140. In some embodiments, the energy band gap of the buffer layer 140 may continuously increase from an interface between the buffer layer 140 and the light absorption layer 130 to an interface between the buffer layer 140 and the front side transparent electrode 150. In this case, the interface between the buffer layer 140 and the light absorption layer 130 may have an energy band gap similar to the energy band gap of the light absorption layer 130, and the interface between the buffer layer 140 and the front side transparent electrode 150 may have an energy band gap similar to the energy band gap of the front side transparent electrode 150.

The buffer layer 140 may be an N-type semiconductor. Thus, the buffer layer 140 may be doped with N-type dopants. A concentration of the N-type dopants may be continuously varied in the buffer layer 140. In more detail, the dopant concentration of the buffer layer 140 may gradually increase or decrease from the interface between the buffer layer 140 and the light absorption layer 130 to the interface between the buffer layer 140 and the front side transparent electrode 150.

Cadmium sulfide (CdS) used as a conventional buffer layer is an environmental pollutant. However, the titanium oxide (TiOₓ) used in the buffer layer 140 according to the inventive concept does not influence environmental pollution. Additionally, the energy band gap of the buffer layer 140 may be continuously varied therein, such that the buffer layer 140 may effectively collect electrons and holes generated in the light absorption layer 130. Thus, the efficiency of the thin film solar cell may be improved.

The front side transparent electrode 150 may be formed on a front side of the solar cell 100 and may perform a window function. Thus, the front side transparent electrode 150 may be formed of a material having high electrical conductivity and high transmittance. For example, the front side transparent electrode 150 may be formed of a zinc oxide (ZnO) layer. The zinc oxide (ZnO) layer may have an energy band gap of about 3.3 eV and a high light transmittance of about 80% or more. The zinc oxide (ZnO) layer may be doped with aluminum (Al) or born (B), such that it may have a low resistance value in the order of 10⁻⁴ Ωcm. For example, when the zinc oxide layer is doped with boron (B), the light transmittance of the zinc oxide layer in a near-infrared region may increase to increase a short circuit current.

In some embodiments, the front side transparent electrode 150 may further include an indium tin oxide (ITO) layer formed on the zinc oxide (ZnO) layer with or without dopants. The ITO layer may have excellent electro-optical properties. The front side transparent electrode 150 may include an intrinsic (or undoped) zinc oxide layer and an N-type zinc oxide layer which are sequentially stacked. The N-type zinc oxide layer has a low resistance.

The anti-reflection layer 170 may reduce reflection loss of light incident to the solar cell 100. Thus, the efficiency of the solar cell 100 may be more improved. For example, the anti-reflection layer 170 may include MgF₂ or SiO₂.

The grid electrode 160 may collect a current generated on a surface of the solar cell 100. The grid electrode 160 may increase the conductivity of the front side transparent electrode 150. The grid electrode 160 may be formed of a metal such as aluminum (Al) or nickel/aluminum (Ni/Al). The grid electrode 160 may block the light. Thus, it may be required to reduce or minimize an area occupied by the grid electrode 160.

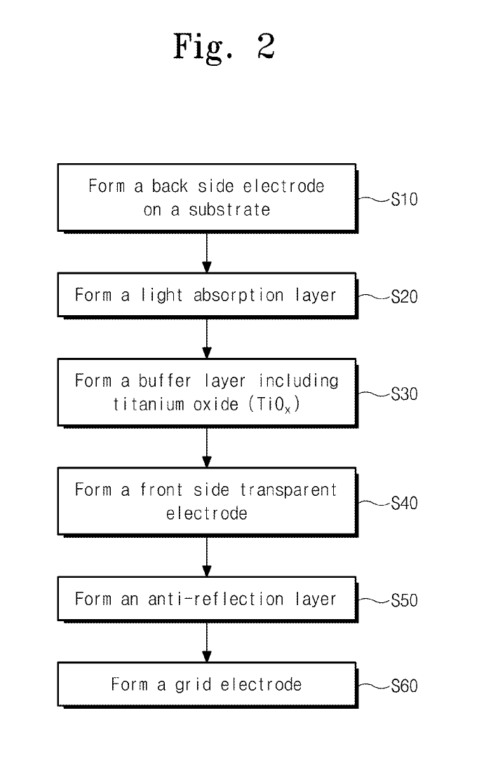

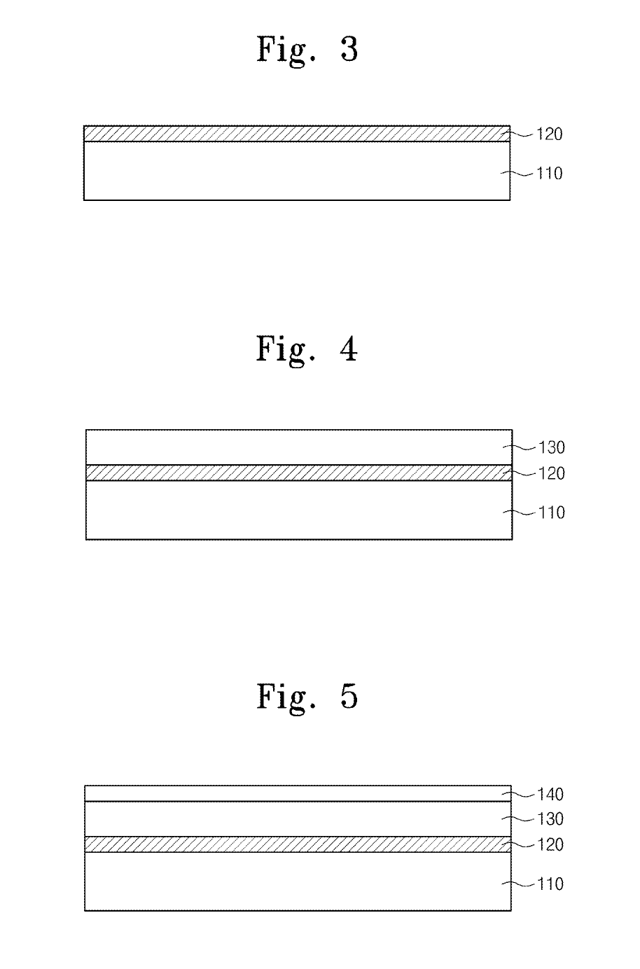

FIG. 2 is a flowchart illustrating a method of fabricating a thin film solar cell according to exemplary embodiments of the inventive concept. FIGS. 3 to 8 are cross-sectional views illustrating a method of fabricating a thin film solar cell according to exemplary embodiments of the inventive concept.

Referring to FIGS. 2 and 3, a back side electrode 120 is formed on a substrate 110 (S10). The substrate 110 may be a soda lime glass substrate, a ceramic substrate including alumina, a metal substrate including stainless steel or a copper tape, or a polymer film. In an embodiment, the substrate 110 may be the soda lime glass substrate.

The back side electrode 120 may be formed of a material having a low resistance and preventing a delamination phenomenon between the substrate 110 and the back side electrode 120 which is caused by coefficients of thermal expansion thereof. For example, the back side electrode 120 may be formed of molybdenum (Mo). The molybdenum (Mo) may have high conductivity, an excellent ohmic contact property, and thermal stability under a selenium (Se) atmosphere. The back side electrode 120 may be formed by a sputtering method, for example, a direct current (DC) sputtering method.

Referring to FIGS. 2 and 4, a light absorption layer 130 is formed on the back side electrode 120 (S20). In some embodiments, the light absorption layer 130 may be a CIGS-based light absorption layer including CuInSe₂, Cu(In, Ga)Se₂, Cu(Al, In)Se₂, Cu(Al, Ga)Se₂, Cu(In,Ga)(S,Se)₂, or (Au,Ag,Cu)(In,Ga,Al)(S,Se)₂. In other embodiments, the light absorption layer 130 may be a CZTS-based light absorption layer formed of Cu₂ZnSn(S, Se)₄. The light absorption layer 130 may include a chalcopyrite-based compound semiconductor. The light absorption layer 130 may have an energy band gap of about 1.15 eV to about 1.2 eV.

The light absorption layer 130 may be formed by a physical method or a chemical method. For example, the physical method may be an evaporation method or a mixture method of a sputtering process and a selenization process. For example, the chemical method may be an electroplating method.

In other embodiments, the light absorption layer 130 may be formed by a co-evaporation method. In still other embodiments, a mixture of nano sizes of particles (e.g., powder or colloid) and a solvent may be formed on the back side electrode 120 by a screen printing process and then the mixture may be reaction-sintered to form the light absorption layer 130.

Referring to FIGS. 2 and 5, a buffer layer 140 is formed on the light absorption layer 130 (S30).

The buffer layer 140 may be formed of titanium oxide (TiOₓ). In some embodiments, an energy band gap of the buffer layer 140 may be substantially uniform within the buffer layer 140. The buffer layer 140 may have an energy band gap between the energy band gap of the light absorption layer 130 and an energy band gap of a front side transparent electrode 150. An atomic ratio “x” of oxygen in the titanium oxide (TiOₓ) may be equal to or greater than 0.75 and smaller than 2.0 (i.e., 0.75≦x<2.0). The energy band gap of the buffer layer 140 may be within a range of about 1.15 eV to about 3.3 eV.

Alternatively, the energy band gap of the buffer layer 140 may gradually increase from an interface between the buffer layer 140 and the light absorption layer 130 to an interface between the buffer layer 140 and the front side transparent electrode 150. In an embodiment, the energy band gap of the buffer layer 140 may increase at a constant rate. In another embodiment, the buffer layer 140 may include a first region of which the energy band gradually increases, and a region of a second region of which the energy band is uniform. The first region may be disposed on the second region. Alternatively, the second region may be disposed on the first region. In this case, the interface between the light absorption layer 130 and the buffer layer 140 may have an energy band gap similar to the energy band gap of the light absorption layer 130, and the interface between the light absorption layer 130 and the front side transparent electrode 150 may have an energy band gap similar to the energy band gap of the front side transparent electrode 150.

The buffer layer 140 may be formed by an atomic layer deposition (ALD) method.

The ALD method may include providing titanium (Ti) precursors in order that the titanium (Ti) precursors are adsorbed onto the light absorption layer 130; providing a first purge gas including an argon (Ar) gas to remove non-adsorbed titanium precursors; providing oxygen precursors to react the adsorbed titanium precursors with the oxygen precursors; providing a second purge gas including an argon gas to remove unreacted oxygen precursors and a byproduct generated by the reaction; and reducing titanium dioxide (TiO₂) formed by the reaction of the adsorbed titanium precursors and the oxygen precursors. The processes described above may constitute one cycle of the ALD method. A plurality of the cycles of the ALD method may be repeatedly performed to form a thin layer including the titanium oxide (TiOₓ). The oxygen precursors may be an oxidation gas supplying oxygen, for example, an oxygen gas, a water vapor, an ozone gas, or a nitrogen dioxide gas.

Reducing the titanium dioxide (TiO₂) may include controlling a plasma condition such as a flow rate of a hydrogen gas, a hydrogen plasma power, a hydrogen plasma temperature, and/or a time maintaining a hydrogen or reduction atmosphere. The plasma condition may be controlled to control a reduction degree of the titanium dioxide (TiO₂). In other words, the atomic ratio “x” of oxygen in the titanium oxide (TiOₓ) may be varied depending on the plasma condition. The atomic ratio “x” of oxygen in the titanium oxide (TiOₓ) may decrease as the reduction degree of the titanium dioxide (TiO₂) increases. The reduction process using hydrogen plasma may be inserted after every ALD cycle or a certain number (n) of ALD cycles, or the reduction process may be carried out after depositing TiO₂ layer.

The energy band gap may be continuously varied in the buffer layer 140. To achieve this, the plasma conditions of the cycles of the ALD method may be different from each other. In case of fabricating a buffer layer having gradually changed band gap energy, the reduction process using hydrogen plasma requires the change of n value or hydrogen plasma conditions during process.

In some embodiments, when the buffer layer 140 is formed, a reduction time of the titanium dioxide (TiO₂) may gradually decrease.

Alternatively, the buffer layer 140 may be formed by a reactive sputtering deposition process. The reactive sputtering deposition process may use a titanium metal as a sputtering target. An oxygen (O₂) gas may be provided during the reactive sputtering deposition process to form the buffer layer 140. During the reactive sputtering deposition process, the amount of the oxygen (O₂) gas may gradually increase, such that the atomic ratio “x” of oxygen may gradually increase in the titanium oxide (TiOₓ). Thus, the energy band gap of the buffer layer 140 may be gradually varied.

The buffer layer 140 may be an N-type semiconductor. Thus, the buffer layer 140 may be doped with N-type dopants. A concentration of the N-type dopants may be continuously varied in the buffer layer 140. In more detail, the dopant concentration of the buffer layer 140 may gradually increase or decrease from the interface between the buffer layer 140 and the light absorption layer 130 to the interface between the buffer layer 140 and the front side transparent electrode 150.

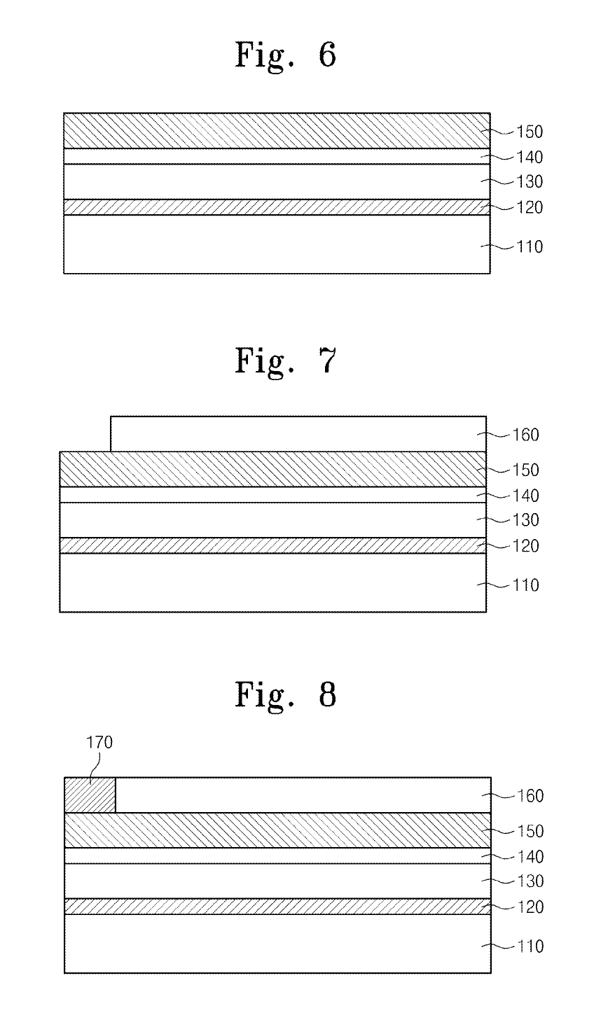

Referring to FIGS. 2 and 6, the front side transparent electrode 150 may be formed on the buffer layer 140 (S40). The front side transparent electrode 150 may be formed of a material having high electrical conductivity and high transmittance.

In some embodiments, the front side electrode 150 may be formed of a zinc oxide (ZnO) layer. The zinc oxide layer may have an energy band gap of about 3.3 eV and a high light transmittance of about 80% or more. The zinc oxide (ZnO) layer may be formed by a radio frequency (RF) sputtering method using a zinc oxide (ZnO) target, a reactive sputtering method using a zinc metal (Zn) target, or an organic metal chemical vapor deposition (MOCVD) method. The zinc oxide (ZnO) layer may be doped with aluminum (Al), gallium (Ga), indium (In) or born (B) for reducing a resistance value thereof.

In other embodiments, the front side transparent electrode 150 may further include an indium tin oxide (ITO) layer formed on the zinc oxide layer. The ITO layer may have excellent electro-optical properties. Additionally, the front side transparent electrode 150 may include an intrinsic (or undoped) zinc oxide layer and an N-type zinc oxide layer which are sequentially stacked. The N-type zinc oxide layer has a resistance lower than that of the intrinsic zinc oxide layer. The ITO layer may be formed by a sputtering method.

Referring to FIGS. 2 and 7, a grid electrode 160 is formed on a partial portion of the front side transparent electrode 150 (S60). The grid electrode 160 may collect a current generated on a surface of the solar cell 100. The grid electrode 160 may be formed of a metal such as aluminum (Al) or nickel/aluminum (Ni/Al). The grid electrode 160 may be formed using a sputtering method. The grid electrode 160 may block the light. Thus, it may be required to reduce or minimize an area occupied by the grid electrode 160.

Referring to FIGS. 2 and 8, an anti-reflection layer 170 is additionally formed on a region of the front side transparent electrode 150 (S60). The anti-reflection layer 170 may reduce reflection loss of light incident to the solar cell 100. The efficiency of the solar cell 100 may be more improved by the anti-reflection layer 170. For example, the anti-reflection layer 170 may include MgF₂. The MgF₂ thin layer may be formed by an E-beam evaporation method.

According to embodiments of the inventive concept, the buffer layer is formed of the titanium oxide (TiOₓ), such that it does not influence environmental pollution. Additionally, the buffer layer may have the gradually varied energy band gap, such that the electrons and holes generated in the light absorption layer may be effectively collected. As a result, the efficiency of the thin film solar cell may be improved.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A thin film solar cell comprising:
a back side electrode formed on a substrate;
a light absorption layer formed on the back side electrode;
a buffer layer formed on the light absorption layer;
a front side transparent electrode formed on the buffer layer;
a grid electrode partially formed on the front side transparent electrode, the grid electrode exposing a top surface of a portion of the front side transparent electrode; and
an anti-reflection layer covering the exposed top surface of the front side transparent electrode,
wherein the buffer layer includes titanium oxide (TiOₓ).

2. The thin film solar cell of claim 1, wherein an atomic ratio “x” of oxygen in the titanium oxide (TiOₓ) is equal to or greater than 0.75 and smaller than 2.0.

3. The thin film solar cell of claim 1, wherein the buffer layer has an energy band gap of about 1.15 eV to about 3.3 eV.

4. The thin film solar cell of claim 3, wherein the energy band gap of the buffer layer gradually increases from an interface between the buffer layer and the light absorption layer to an interface between the buffer layer and the front side transparent electrode.

5. The thin film solar cell of claim 1, wherein the buffer layer includes N-type dopants.

6. The thin film solar cell of claim 1, wherein the buffer layer has a dopant concentration gradually increasing from an interface between the buffer layer and the light absorption layer to an interface between the buffer layer and the front side transparent electrode.

7. The thin film solar cell of claim 1, wherein the buffer layer has a dopant concentration gradually decreasing from an interface between the buffer layer and the light absorption layer to an interface between the buffer layer and the front side transparent electrode.

8. The thin film solar cell of claim 1, wherein the light absorption layer is a CIGS-based light absorption layer or a CZTS-based light absorption layer.

9. A method of fabricating a thin film solar cell comprising:
forming a back side electrode on a substrate;
forming a light absorption layer on the back side electrode;
forming a buffer layer on the light absorption layer;
forming a front side transparent electrode on the buffer layer;
forming a grid electrode on a partial portion of the front side transparent electrode,
forming an anti-reflection layer on the top surface of the front side transparent electrode exposed the grid electrode; and
wherein the buffer layer includes titanium oxide (TiOₓ).

10. The method of claim 9, wherein the buffer layer is formed using an atomic layer deposition (ALD) method or a reactive sputtering method.

11. The method of claim 10, wherein the ALD method comprises:
providing titanium (Ti) precursors in order that the titanium (Ti) precursors are adsorbed onto the light absorption layer;
providing a first purge gas including an argon (Ar) gas to remove non-adsorbed titanium (Ti) precursors;
providing oxygen precursors to react the titanium (Ti) precursors adsorbed on the light absorption layer with the oxygen precursors, thereby forming titanium dioxide (TiO₂);
providing a second purge gas including an argon gas to remove unreacted oxygen precursors and a byproduct generated by the reaction of the adsorbed titanium (Ti) precursors and the oxygen precursors; and
reducing the titanium dioxide (TiO₂).

12. The method of claim 10, wherein the reactive sputtering method uses a titanium metal as a sputtering target; and
wherein the partial pressure of oxygen (O₂) gas gradually increases during the reactive sputtering method.

13. The method of claim 9, wherein an energy band gap of the buffer layer is greater than an energy band gap of the light absorption layer and is smaller than an energy band gap of the front side transparent electrode; and
wherein the energy band gap of the buffer layer gradually increases from the energy band gap of the light absorption layer to the energy band gap of the front side transparent electrode.

14. The method of claim 9, further comprising:
doping the buffer layer with N-type dopants,
wherein a dopant concentration of the buffer layer is gradually varied in the buffer layer.

15. The method of claim 9, wherein the light absorption layer is a CIGS-based light absorption layer or a CZTS-based light absorption layer.
